(19) United States
(12) Patent Application Publication
(10) Pub. No.: US 2008/0305412 A1
(43) Pub. Date: Dec. 11, 2008

(54) NEAR-FIELD EXPOSURE MASK AND NEAR-FIELD EXPOSURE METHOD

(75) Inventors: Akira Terao, Yokohama-shi (JP); Toshiki Ito, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/133,753

(22) Filed: Jun. 5, 2008

(30) Foreign Application Priority Data
Jun. 11, 2007 (JP) 2007-153620

(51) Int. Cl. G03F 1/00; G03F 7/22

(52) U.S. Cl. 430/5; 430/322

(57) ABSTRACT

A near-field exposure mask and a near-field exposure method, the exposure mask including a light blocking film having an opening and configured to expose an object to be exposed by use of near-field light generated at the opening, wherein the opening of the exposure mask has a plurality of processing pitches and an opening width, and wherein, when the opening width of the opening is denoted by s (nm), the processing pitch is denoted by p (nm), a dimensionless parameter is denoted by E and coefficients are denoted by a and b, the opening has the opening width which satisfies equation (1), equation (2), equation (3) and equation (4) below

s=ap−b+18.82E (1)

0.67≦E≦1 (2)

0.056≦a≦0.083 (3)

2.53≦b<5.08. (4)

### FIELD OF THE INVENTION AND RELATED ART

This invention relates to a near-field exposure mask and a near-field exposure method.

In recent years, in the field of electronic devices such as semiconductor devices which need microprocessing, further device densification and integration have been required more and more. In order to meet these requirements, further miniaturization of the pattern is indispensable.

Projection exposure apparatus has been the mainstream in recent years to satisfy these requests. The projection exposure apparatus generally comprises a light source, an illumination optical system, a mask having a pattern drawn thereon, a projection optical system and a stage for scanning an object to be exposed. The resolution limit is about the wavelength of the light.

In order to improve the resolution in such structure, liquid immersion exposure technology has been proposed in which the exposure is carried out while a projection optical system and an object to be exposed are immersed in a liquid. However, this causes problems of bulkiness of the projection optical system and rise of the apparatus cost due to higher accuracy complexity of the device structure.

On the other hand, as one low-cost microprocessing method in which the resolution can be free from the wavelength of light, a near-field exposure method has been proposed in which near-field light generated at minute opening formed in a light blocking film on the surface of an exposure mask plane is used.

Generally, since the intensity of near-field light decreases steeply with the distance from the minute openings, practically it is necessary to place the object to be exposed and the minute openings very close to each other, with a spacing of 100 m or less. Furthermore, it is known that the near-field light intensity adjacent the minute openings changes with the thickness of the light blocking film on the exposure mask surface, the pitch of the minute openings or the opening width.

Therefore, in order to transfer the pattern to a resist with good precision based on the near-field light, it is important to control the near-field light distribution to be formed adjacent the minute openings on the basis of the light blocking film on the exposure mask surface or the dimension of the minute openings.

Japanese Laid-Open Patent Application No. 2004-29748 has clarified the relationship among the thickness of the light blocking film, the opening width of the minute openings and the near-field light intensity, based on the thickness of the light blocking film on the exposure mask surface, and has determined the thickness of the light blocking film providing desired near-field light intensity.

However, although the aforementioned Japanese Laid-Open Patent Application No. 2004-29748 has clarified the relationship with regard to the intensity of near-field light, it mentions nothing about the pitch of the opening pattern and the spatial distribution of the near-field light intensity.

Particularly, in order that a minute-opening pattern formed on an exposure mask is exposed simultaneously at the ratio of 1:1, it is very important to specify the spatial distribution of near-field light intensity.

### SUMMARY OF THE INVENTION

Hence, the present invention provides a near-field exposure mask and a near-field exposure method by which an opening pattern having a plurality of processing pitches can be exposed simultaneously and by which unit-magnification exposure of 1:1 ratio is enabled.

In accordance with an aspect of the present invention, there is provided a near-field exposure mask, comprising: a light blocking film having an opening and configured to expose an object to be exposed by use of near-field light generated at the opening, wherein the opening of the exposure mask has a plurality of processing pitches and an opening width, and wherein, when the opening width of the opening is denoted by s (nm), the processing pitch is denoted by p (nm), a dimensionless parameter is denoted by E and coefficients are denoted by a and b, the opening has the opening width which satisfies equation (1), equation (2), equation (3) and equation (4) below

s=ap−b+18.82E (1)

0.67≦E≦1 (2)

0.056≦a≦0.083 (3)

2.53≦b≦5.08 (4).

In accordance with another aspect of the present invention, there is provided a near-field exposure method to be used with a near-field exposure mask having a light blocking film with an opening, to expose an object to be exposed by use of near-field light generated at the opening, comprising the steps of: preparing the exposure mask so that the opening of the exposure mask has a plurality of processing pitches and an opening width, wherein the opening width of the opening is determined so that, when the opening width is denoted by s (nm), the processing pitch is denoted by p (nm), a dimensionless parameter is denoted by E and coefficients are denoted by a and b, the opening width satisfies equation (1), equation (2), equation (3) and equation (4) below

s=ap−b+18.82E (1)

0.67≦E≦1 (2)

0.056≦a≦0.083 (3)

2.53≦b≦5.08 (4); and

irradiating the exposure mask prepared by said preparing step with exposure light to thereby expose the object to be exposed.

The object to be exposed may be comprised of a substrate having high reflectivity with respect to the exposure light, and a resist layer having a thickness not less than 120 nm and not greater than 150 nm.

The object to be exposed may have a multilayered structure comprised of a multilayered resist layer including at least an upper-layer resist layer and a lower-layer resist layer, and a substrate having high reflectivity with respect to the exposure light, wherein the upper-layer resist layer may have a thickness not less than 5 nm and not greater than 15 nm while the multilayered resist layer may have a thickness not less than 120 nm and not greater than 150 nm.

Briefly, in accordance with the present invention, a near-field exposure mask and a near-field exposure method by which an opening pattern having a plurality of processing pitches can be simultaneously exposed and by which unit-magnification exposure of 1:1 is enabled, are accomplished.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic view illustrating a structural example of a near-field exposure mask in a first embodiment of the present invention.

FIG. 2 is a diagram for explaining the general structure of an object to be exposed in the first embodiment of the present invention.

FIG. 3 is a diagram for explaining the outline when a near-field photomask in the first embodiment of the present invention and an object to be exposed are used to perform the near-field exposure.

FIG. 4 is a graph illustrating an example of near-field light intensity adjacent the close-contact interface between a near-field photomask of FIG. 3 produced by FDTD method in the first embodiment of the present invention and the object to be exposed.

FIG. 5 is a graph for explaining changes of the near-field light intensity with the opening width and the processing pitch in the first embodiment of the present invention.

FIG. 6 is a graph for explaining the relationship among the processing pitch, opening width and dimensionless parameter E, which provides the same near-field light intensity with a distance which is ¼ of the processing pitch and a Z-direction depth of 10 nm in the first embodiment of the present invention.

FIG. 7 is a flow chart for explaining the outline of near-field exposure method in a second embodiment of the present invention.

FIGS. 8A-8E are diagrams showing an example of the processes for making a near-field photomask in the second embodiment of the present invention.

FIG. 9 is a diagram for explaining a close-contact exposure method for a membrane photomask and an object to be exposed, in the second embodiment of the present invention.

FIGS. 10A-10C are diagrams for explaining the processes for transferring a high aspect pattern, in the second embodiment of the present invention.

FIG. 11 is a graph for explaining the relationship between the Z-direction depth and contrast in the second embodiment of the present invention.

FIG. 12 is a graph for explaining the relationship between the resist layer thickness and contrast in the second embodiment of the present invention.

### DESCRIPTION OF THE PREFERRED EMBODIMENTS

Preferred embodiments of the present invention will now be described with reference to the attached drawings.

The structure in which the opening of the near-field exposure mask of the present invention has an opening width which satisfies equation (1), equation (2), equation (3) and equation (4) mentioned above has been found by the inventors paying specific attention to the relationship between the pitch of the opening pattern and the spatial distribution of the near-field light intensity.

Thus, with the near-field exposure mask having a structure according to the present invention as described above, the near-field light intensity on the object to be exposed becomes uniform at a distance ¼ of the corresponding processing pitch from the opening center of each minute opening formed in the light blocking film of the exposure photomask.

As a result of this, the same dose amount is assured constantly at the boundary between the exposed area and the unexposed area of the object to be exposed. Thus, the opening pattern having a plurality of processing pitches can be exposed at the same time, and yet unit-magnification exposure of 1:1 ratio is enabled.

Furthermore, with the near-field exposure method having processes according to the present invention as described above, the near-field light intensity on the object to be exposed becomes uniform at a distance ¼ of the corresponding processing pitch from the opening center of each minute opening formed in the light blocking film of the near-field exposure mask.

As a result of this, the same dose amount is assured constantly at the boundary between the exposed area and the unexposed area of the object to be exposed. Thus, the opening pattern having a plurality of processing pitches can be exposed at the same time, and yet unit-magnification exposure of 1:1 ratio is enabled.

Consequently, a pattern comprised of a plurality of line-and-space patterns (1:1 patterns) having different pitches and linewidths can be formed simultaneously and very precisely.

Now, some preferred embodiments of the present invention will be explained.

### Embodiment 1

A first embodiment of the present invention will be explained with reference to a near-field exposure mask which is structured in accordance with the present invention.

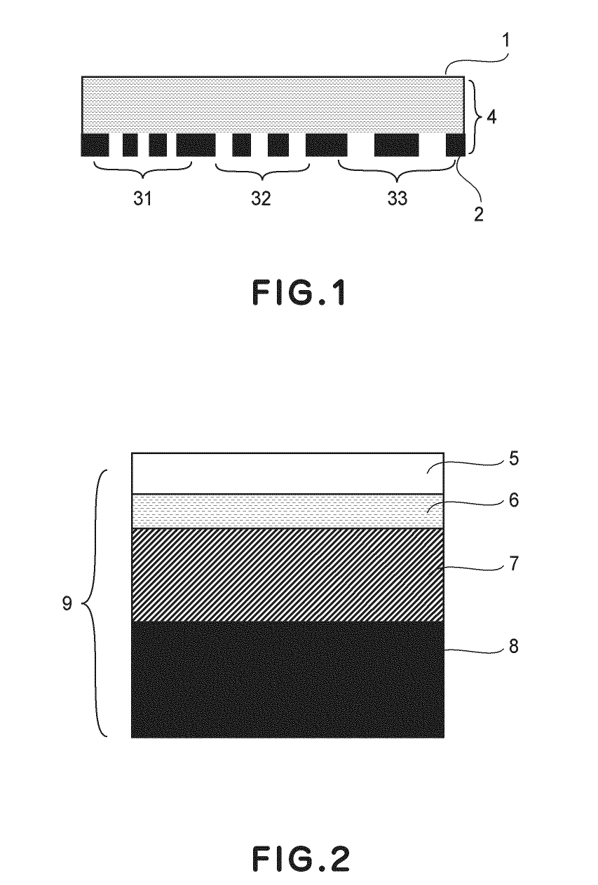

FIG. 1 is a diagram illustrating a structural example of a near-field exposure mask according to this embodiment of the present invention.

Denoted in FIG. 1 at 1 is a mask base material, and denoted at 2 is a light blocking film. Denoted at 4 is a near-field photomask, and denoted at 31 is a minute opening pattern. Denoted at 32 is a minute opening pattern, and denoted at 33 is a minute opening pattern.

The present embodiment uses exposure light having a wavelength of 365 nm.

The near-field photomask 4 is comprised of the mask base material 1, the light blocking film 2 and the minute opening pattern 3 for generating near-field light.

The material of mask base material 1 is silicon nitride, and it has a thickness of around 400 nm. The material of the light blocking film 2 is amorphous silicon, and it has a thickness of around 50 nm. The light blocking film 2 is formed with a minute opening pattern 31, a minute opening pattern 32 and a minute opening pattern 33 each having a different processing pitch.

In this example, the processing pitch of them is 44 nm, 72 nm and 130 nm, respectively.

Here, with regard to the processing pitch and the opening width of each minute opening pattern, if the opening width is denoted by s (nm) and the processing pitch is denoted by p (nm), the opening width is set to satisfy the equation (5) below.

s=0.073p+14.63 (5)

This coincides with a case where a=0.073, b=4.19 and E=1 in equation (1) having been mentioned in the summary of the invention.

It follows from equation (5) above that the opening width in association with the processing pitch of the respective minute opening patterns are:

18 nm for the minute opening pattern 31;

20 nm for the minute opening pattern 32; and

24 nm for the minute opening pattern 33.

FIG. 2 is a diagram for explaining general structure of the object to be exposed in the present embodiment.

In FIG. 2, denoted at 5 is an upper-layer resist layer, and denoted at 6 is an SOG layer. Denoted at 7 is a lower-layer resist layer, and denoted at 8 is a substrate. Denoted at 9 is the object to be exposed.

The object to be exposed 9 of the present embodiment is comprised of a multilayered structure having a multilayered resist layer including the upper-layer resist layer 5, SOG layer 6 and lower-layer resist layer 7, as well as the substrate 8 having high reflectivity to exposure light.

The upper-layer resist layer 5 reacts when irradiated with exposure wavelength, and it is patterned through a development process.

With regard to the thickness of each layer, approximately, the upper-layer resist layer 5 has a thickness 10 nm, the SOG layer 6 has a thickness 20 nm, the lower-layer resist layer 7 has a thickness 100 nm, and the substrate 8 has a thickness 500 um.

Preferably, the upper-layer resist layer should have a thickness in the range of not less than 5 nm and not greater than 15 nm, and the multilayer resist layer should have a thickness in the range of not less than 120 nm and not greater than 150 nm.

Generally, the upper-layer resist layer 5 and the lower-layer resist layer 7 may be made of a resin system material, while the material of substrate 8 may be Si.

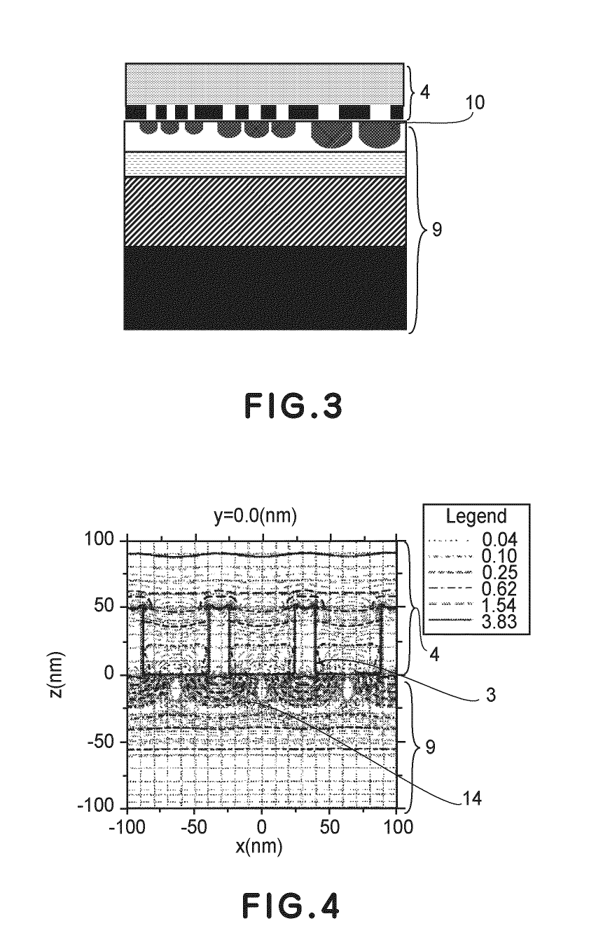

FIG. 3 is a diagram for explaining outline when near-field exposure is carried out using the near-field photomask 4 and the object 9 to be exposed.

In FIG. 3, similar reference numerals as of FIG. 1 and FIG. 2 are assigned to corresponding structures. Thus, description of the same will be omitted here.

In FIG. 3, denoted at 10 is near-field light. In the near-field exposure, exposure light is projected to the near-field photomask 4 while the photomask 4 and the upper-layer resist layer 5 of the object 9 to be exposed are closely contacted to each other. Then, the upper-layer resist layer 5 is exposed with the near-field light 10 which is generated adjacent the minute opening patterns.

More specifically, in the upper-layer resist layer 5, the zone where the intensity of near-field light is relatively high provides an exposed area while the zone where the intensity is relatively low defines an unexposed area.

Here, it is known that the intensity of near-field light 10 or the spatial distribution thereof changes complicatedly with the pitch and opening width of the minute opening pattern and the thickness and material of the laminar structure of the object 9 to be exposed.

Furthermore, electromagnetic-field analysis method based on FDTD method is known as a technique for predicting the intensity of the near-field light and the spatial distribution thereof. The inventors have applied the FDTD method to the near-field exposure being depicted in FIG. 3, and have succeeded in predicting the intensity and spatial distribution of near-field light 10.

FIG. 4 is a diagram showing an example of the near-field light intensity adjacent the close-contact interface between the near-field photomask 4 shown in FIG. 3 and the object 9 to be exposed, obtained in accordance with the FDTD method.

In FIG. 4, similar reference numerals as of FIG. 1 and FIG. 2 are assigned to corresponding structures. Thus, description of the same will be omitted here.

In FIG. 4, denoted at 14 are isointensity contour lines of the near-field light intensity distribution.

Here, for convenience, a direction which is perpendicular to the near-field photomask 4 is depicted as Z, and the horizontal direction is depicted as X. By the isointensity contour lines 14, the spatial distribution of the near-field light intensity is illustrated.

Next, the condition for forming a minute surface-unevenness pattern of 1:1 such as, for example, a line-and-space pattern at the upper-layer resist layer 5 of the object 9 to be exposed will be explained.

Now, the position corresponding to ¼ of the pitch of the minute openings of the minute opening patterns 3 in the X-direction and from the opening center of one minute opening, and at the Z-direction position corresponding to the interface between the upper-layer resist layer 5 and the SOG layer 6, is specifically considered.

This position corresponds to the boundary between the exposed area and the unexposed area of the upper-layer resist layer 5, in the line-and-space pattern of 1:1.

In order that a plurality of different processing pitches are exposed simultaneously by 1:1, at distances corresponding to ¼ of individual minute opening patterns, respectively, the near-field light intensity at the interface between the upper-layer resist layer 5 and the SOG layer 6 should be the same.

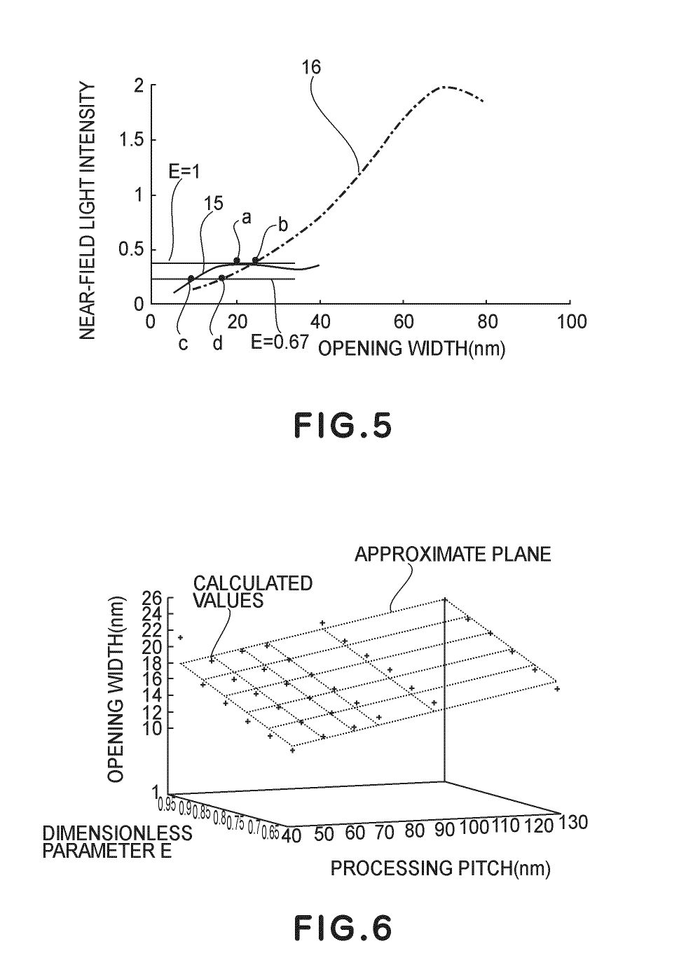

FIG. 5 is a diagram for explaining, in a case where the processing pitch is 44 nm and 130 nm, changes of the near-field light intensity relative to the opening width at the distances of ¼ of the processing pitches and at a position of 10 nm depth in the Z direction.

The change of near-field light intensity in the case of processing pitch 44 nm is depicted by line 15, while the change of near-field light intensity in the case of processing pitch 130 nm is illustrated by line 16.

The dimensionless parameter E takes the near-field light intensity shown in FIG. 5 at the maximum of line 15 as 1.

Points a and b denotes the opening width of the processing pitch 44 nm which provides the maximum near-field light intensity if the dimensionless parameter is E=1, namely, when the processing pitch is 44 nm, and the opening width of the processing pitch 130 nm which provides a value equivalent to that intensity.

In FIG. 5, points a and b illustrate that the opening width is 20 nm for the processing pitch 44 nm, and the opening width is 24 nm for the processing pitch 130 nm.

Similarly, points c and d illustrate a case where the dimensionless parameter E is 0.67, and these depict that the opening width is 11.5 nm for the processing pitch 44 nm, and the opening width is 18 nm for the processing pitch 130 nm.

In FIG. 5 by providing these opening widths depicted by points a and b or points c and d in relation to individual processing pitches, the same near-field light intensity is accomplished at the exposed area and the unexposed area of the resist despite that the processing pitch is different. Hence, these can be exposed simultaneously.

It is to be noted here that, when the opening width is changed in the minute opening pattern of the processing pitch 44 nm, the dimensionless parameter E takes the maximum of the obtained near-field light intensity as 1.

Therefore, what is shown in FIG. 5 is unchangeable for the irradiated intensity of exposure light projected to the near-field photomask 4.

FIG. 6 is a graph which plots the relationship among the processing pitch p (nm), dimensionless parameter E and opening width s (nm) under the condition of processing pitch not less than 44 nm and not greater than 130 nm, assuring the same near-field light intensity at the distanced of ¼ of the processing pitch and at the position of Z-direction depth of 10 nm.

In a three-dimensional space having axes defined by the processing pitch, dimensionless parameter and opening width, the plotting mentioned above can be roughly approximated by a plane equation such as equation (6) below.

s=0.073p−4.19+18.82E (6)

Furthermore, if the fitting precision is considered, the plane equation of equation (6) of FIG. 6 can be sufficiently approximated by equation (7) below.

s=ap−b+18.82E (7)

wherein a and b are in the range defined by equation (8) and equation (9) below.

0.056≦a≦0.083 (8)

2.53≦b≦5.08 (9)

Next, the process of determining the opening width to be provided at the near-field photomask 4 based on equation (6) will be explained.

The processing pitch for processing the object 9 to be exposed is determined by the specifications of the product to be obtained by utilizing that object 9.

Then, in consideration of the resist sensitivity and irradiation intensity of exposure light to the near-field photomask 4, the dimensionless parameter in the range not less than 0.67 and not greater than 1 is chosen, by which a desired exposure intensity is obtainable at the upper-layer resist layer 5.

Based on the value of the dimensionless parameter chosen here, the opening widths in relation to respective processing pitches can be determined. In this embodiment, for the processing pitches of 44 nm, 72 nm and 130 nm, the dimensionless parameter E takes 1 and, by doing so, minute opening patterns 31, 32 and 33 shown in FIG. 1 can have opening widths of 18 nm, 20 nm and 24 nm, respectively.

By projecting exposure light to the near-field photomask 4 which comprises a plurality of minute opening patterns 31, 32 and 33 having processing pitches and opening widths determined in the manner described above, patterns having different processing pitches can be simultaneously transferred onto the object 9, yet by unit-magnification exposure of 1:1.

### Embodiment 2

A second embodiment of the present invention will be explained with reference to a near-field exposure method using a near-field photomask provided in the first embodiment.

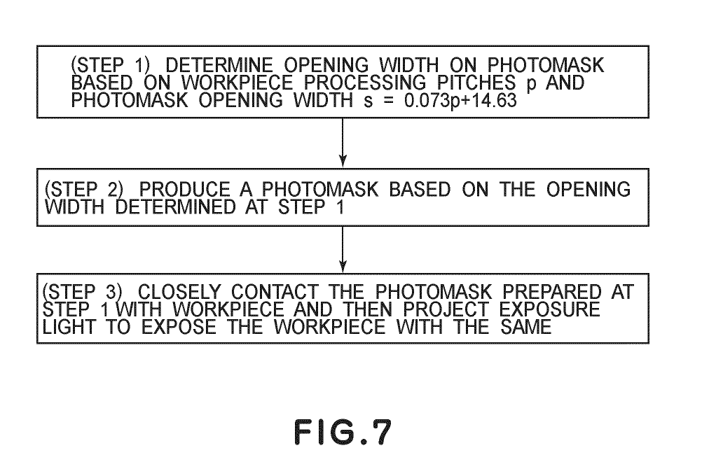

FIG. 7 is a flow chart explaining the outline of the near-field exposure method according to the present embodiment.

This embodiment as well uses a near-field field photomask and an object to be exposed, having a structure similar to that of the first embodiment of the present invention.

First of all, at step 1, if the processing pitch for processing the object to be exposed is p (nm) and the opening width of the minute opening pattern on the light blocking film of the photomask is s (nm) with, the opening width of the minute opening pattern to be provided at the photomask is so determined to satisfy equation (5).

Subsequently, at step 2, an exposure mask with openings having the opening width determined by the preceding step for determining the opening width is prepared.

After that, at step 3, the exposure photomask prepared at the step 2 is used and exposure light is projected to the exposure photomask, by which the object to be exposed is exposed.

The manner of determining the opening width of the minute opening pattern at step 1 is the same as has been described with reference to the first embodiment.

Like the first embodiment, the processing pitch is 44 nm, 72 nm and 130 nm, and the opening width of the minute opening pattern is 18 nm, 20 nm and 24 nm.

At step 2, the near-field photomask 4 with minute opening patterns 31, 32 and 33 having the opening width and processing pitch as determined by step 1 is made.

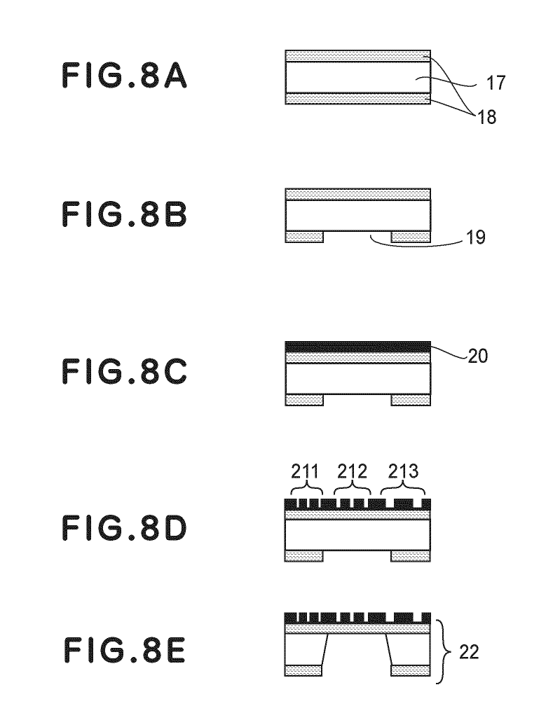

FIG. 8A through FIG. 8E show an example of processes for making the near-field photomask 4 at step 2.

In FIG. 8A, a silicon nitride film 18 is formed on both sides of a silicon substrate 17, with a thickness of about 400 nm.

In FIG. 8B, a back-etch hole 19 is formed at the silicon substrate bottom face.

In FIG. 8C, a film of amorphous silicon which provides a light blocking film 20 is layered on the substrate surface, to around 50 nm.

In FIG. 8D, minute opening patterns 211, 212 and 213 having processing pitches and opening widths determined by step 1 are patterned on the light blocking film 20 by using an electron-beam lithographic device.

In FIG. 8E, the silicon substrate 17 is removed from the back-etch hole 19 through anisotropic wet etching using KOH, so that the region where the minute opening pattern has been patterned is made into a very thin film. Thus, a membrane photomask 22 of a structure equivalent to the near-field photomask 4 is obtained.

At step 3, the membrane photomask 22 prepared by step 2 and the upper-layer resist layer 5 of object to be exposed 9 are brought into close contact with each other.

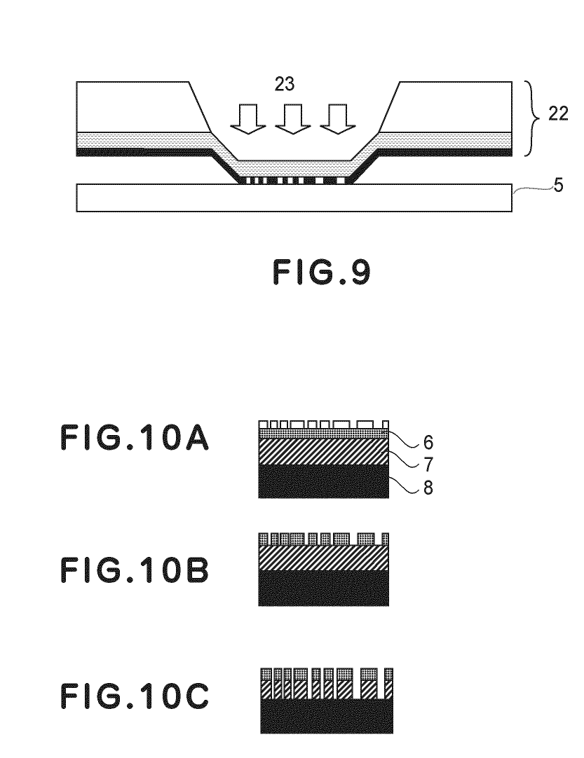

FIG. 9 shows an example of how to performing the close contact at step 3.

The membrane photomask 22 is attached to a pressure container (not shown) and then it is pressurized. Due to the applied pressure 23, the patterned region of the membrane photomask 22 having been made into a very thin film is flexed such that it is closely contacted to the upper-layer resist layer 5. After the close contact, the membrane photomask 22 is irradiated with the exposure light. Thus, the upper-layer resist layer 5 of the object 9 to be exposed is exposed with near-field light generated adjacent the minute opening patterns 211, 212 and 213.

The exposure process based on the near-field exposure method of the present embodiment is such as described above. Here, the upper-layer resist layer 5 will have a thickness of around 10 nm which is insufficient to be widely used in the industrial field of LSI manufacture, for example.

Hence, in order to correct this, a pattern forming process may be made after the exposure of the object 9. This will be explained below.

After the exposure, a development process is carried out to the upper-layer resist layer 5. Here, if the upper-layer resist layer 5 is a positive type resist, the exposed area will be removed by the development step. If it is a negative resist, the unexposed area will be removed by the development step.

The present embodiment will now be explained as using a positive type resist.

FIGS. 10A through 10C illustrate the processes for transferring a high aspect pattern.

In FIG. 10A, the upper-layer resist layer 5 of the exposed area is removed by the development step.

In FIG. 10B, the SOG layer 6 is etched by using a fluorine-based gas while the remaining upper-layer resist layer 5 is used as a mask.

In FIG. 10C, the lower-layer resist layer 7 is etched by using an oxygen-based gas, while the etched SOG layer 6 is used as a mask.

Here, the lower-layer resist layer 7 is made of phenol resin having a resistance to the fluorine-based gas, among resin series materials.

In order to apply a step of transferring a high aspect pattern such as shown in FIG. 10, the object to be exposed should preferably have a laminated structure including at least three layers or more upon the substrate as shown in FIG. 3.

With regard to the structure of the object 9 to be exposed, the upper-layer resist layer 5 should preferably have a thickness of 10 nm. However, equation (5) applies even in the range of 5 nm to 15 nm.

Since the thickness of the SOG layer 6 has substantially no influence on the near-field light intensity at the upper-layer resist layer or the spatial distribution thereof, the selectable range is wide. However, for the purpose of etching, it should desirably be 20 nm.

It is particularly desirable that the sum of the upper-layer resist layer 5, SOG layer 6 and the lower-layer resist layer 7, namely, the thickness of the multilayered resist layer, should be 130 nm. However, it may be not less than 120 nm and not greater than 150 nm.

The reason for this is as follows. The near-field light generated at the minute opening pattern 3 of the photomask 4 is converted into propagation light, and thus a progressive wave propagating in the upper-layer resist layer 5 and the SOG layer 6 is produced. Furthermore, due to the reflection of the progressive wave at the interface between the substrate 8 and the lower-layer resist layer 7, a reflected wave is generated and, as a result of this, a standing wave is produced in the multilayered resist layer.

If the upper-layer resist layer 5 has a thickness of around 10 nm while the thickness of the multilayered resist layer is around 130 nm, a node of the standing wave is formed at the interface between the upper-layer resist layer 5 and the SOG layer 6.

In that occasion, as compared with a case where the reflectivity of the substrate 8 to the exposure light is low or a case where the thickness of the upper-layer resist layer 5 or the thickness of the upper-layer resist layer 5, SOG layer 6 and lower-layer resist layer 7 largely deviates from the aforementioned range, the intensity of the near-field light for exposing the upper-layer resist layer 5 is intensified.

In consideration of this, with regard to the substrate 8, use of a material having high reflectivity to exposure light is preferable and, in present embodiment, silicon is used.

The intensifying effect to the near-field light intensity due to the standing waves in the resist layer was quantitatively investigated. The results are as follows.

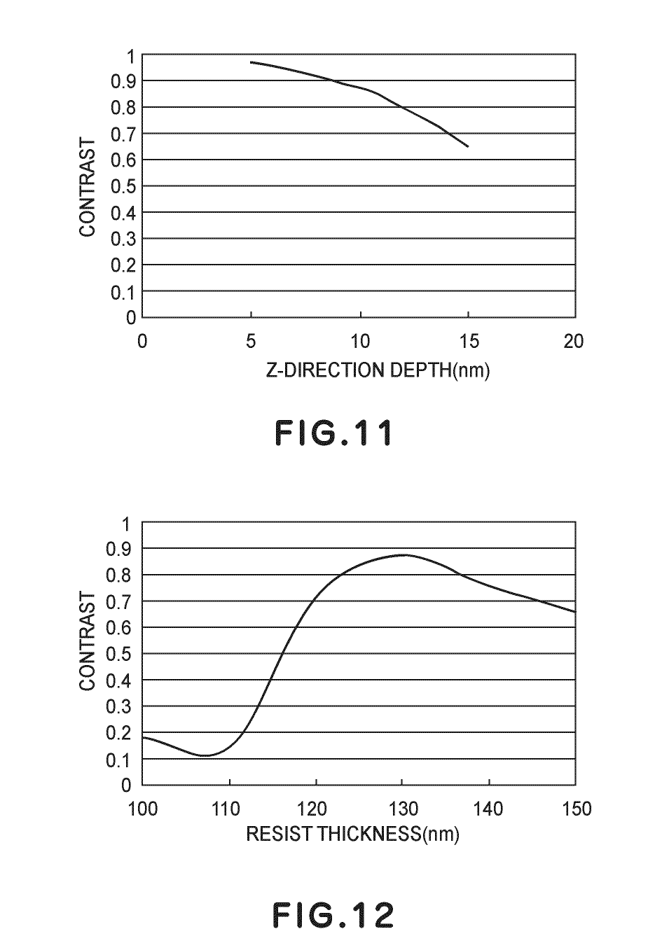

Referring to FIG. 11, the relationship between the Z-direction depth and the contrast will be explained.

FIG. 11 illustrates changes of contrast in a case where the processing pitch is 44 nm, the opening width is 15 nm, and the upper-layer resist thickness is 130 nm, wherein the Z-direction depth is taken at the position from the upper-resist layer surface with respect to negative (−) Z direction as viewed in FIG. 6.

Here, the contrast is the quantity which can be detected by equation (10) below wherein Imax is the maximum in the near-field light intensity distribution in one section along the X-direction at certain position in the Z direction, and Imin is the minimum thereof.

Contrast=(Imax−Imin)/(Imax+Imin) (10)

If the Z depth is 15 nm or less, a contrast of 0.65 or more is obtainable. This is a sufficient condition for exposure of the upper-layer resist layer.

Namely, the range up to 15 nm form the surface of the upper-layer resist layer can be exposed sufficiently.

Furthermore, according to FIG. 11, the smaller the Z-direction depth is, the better the result is. However, since the lower limit that a resist layer can be applied by a spin coating method or the like is about 5 nm, it may be practical that the thickness of the upper-layer resist layer 5 is not less than 5 nm and not greater than 15 nm.

Next, referring to FIG. 12, the relationship between the resist layer thickness and the contrast will be explained.

FIG. 12 illustrates the resist layer thickness at the Z-direction depth of 10 nm and changes of contrast when the processing pitch is 44 nm and the opening width is 15 nm.

The resist layer thickness that provides an optimum contrast is 130 nm. However, with a multilayered resist layer thickness of not less than 120 nm and not greater than 150 nm, preferably a contrast of 0.65 or higher as described hereinbefore is obtainable.

The multilayered resist structure of the object 9 to be exposed will be desirable when deep processing is necessary as in the case of LSI production. Hence, if the processing depth may be 10 nm or less, the object to be exposed may be comprised of a single-layered resist layer and a substrate.

In that occasion, the thickness of the single-layered resist layer may most preferably be 130 nm. It may preferably be not less than 120 nm and not greater than 150 nm. The substrate may preferably be made of a material having high reflectivity to exposure light, such as silicon, for example.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2007-153620 filed Jun. 11, 2007, for which is hereby incorporated by reference.

What is claimed is:

1. A near-field exposure mask, comprising:
a light blocking film having an opening and configured to expose an object to be exposed by use of near-field light generated at the opening,
wherein the opening of the exposure mask has a plurality of processing pitches and an opening width, and
wherein, when the opening width of the opening is denoted by s (nm), the processing pitch is denoted by p (nm), a dimensionless parameter is denoted by E and coefficients are denoted by a and b, the opening has the opening width which satisfies equation (1), equation (2), equation (3) and equation (4) below
s=ap−b+18.82E (1)
0.67≦E≦1 (2)
0.056≦a≦0.083 (3)
2.53≦b≦5.08 (4).

2. A near-field exposure method to be used with a near-field exposure mask having a light blocking film with an opening, to expose an object to be exposed by use of near-field light generated at the opening, comprising the steps of:
preparing the exposure mask so that the opening of the exposure mask has a plurality of processing pitches and an opening width, wherein the opening width of the opening is determined so that, when the opening width is denoted by s (nm), the processing pitch is denoted by p (nm), a dimensionless parameter is denoted by E and coefficients are denoted by a and b, the opening width satisfies equation (1), equation (2), equation (3) and equation (4) below
s=ap−b+18.82E (1)
0.67≦E≦1 (2)
0.056≦a−0.083 (3)
2.53≦b≦5.08 (4); and
irradiating the exposure mask prepared by said preparing step with exposure light to thereby expose the object to be exposed.

3. A method according to claim 2, wherein the object to be exposed is comprised of a substrate having high reflectivity with respect to the exposure light, and a resist layer having a thickness not less than 120 nm and not greater than 150 nm.

4. A method according to claim 3, wherein the object to be exposed has a multilayered structure comprised of a multilayered resist layer including at least an upper-layer resist layer and a lower-layer resist layer, and a substrate having high reflectivity with respect to the exposure light, and wherein the upper-layer resist layer has a thickness not less than 5 nm and not greater than 15 nm while the multilayered resist layer has a thickness not less than 120 nm and not greater than 150 nm.
